(19) United States
(12) Patent Application Publication
(10) Pub. No.: US 2011/0081768 A1
(43) Pub. Date: Apr. 7, 2011

(54) WORKPIECE DIVIDING METHOD

(75) Inventor: Masaru Nakamura, Ota-Ku (JP)

(73) Assignee: DISCO CORPORATION, Tokyo (JP)

(21) Appl. No.: 12/885,675

(22) Filed: Sep. 20, 2010

(30) Foreign Application Priority Data
Oct. 1, 2009 (JP) 2009-229382

(51) Int. Cl. H01L 21/78

(52) U.S. Cl. 438/462; 257/E21.599

(57) ABSTRACT

In a workpiece dividing method, an expansion tape is stuck to an adhesive film side of a workpiece in a state where an adhesive film is stuck to the rear surface of a wafer. Respective positions of the predetermined dividing lines on the front surface of the wafer are detected. On the basis of information on the detected predetermined dividing lines, a laser beam passing through the wafer from the front surface of the wafer is focused on and directed to the front surface or inside of the adhesive film to form modified areas on the front surface of or in the inside of the adhesive film. On the basis of information on the detected predetermined dividing lines, a laser beam passing through the wafer from the front surface of the wafer is focused on and directed to the inside of the wafer to form modified areas in the inside of the wafer. The expansion tape is expanded to divide the workpiece along the predetermined dividing lines with the modified areas taken as start points.

### BACKGROUND OF THE INVENTION

1. Field of the Invention

The present invention relates to a dividing method of dividing a workpiece in which an adhesive film is stuck to a wafer such as a semiconductor wafer or the like.

2. Description of the Related Art

In the past, a semiconductor element and a support member for mounting the semiconductor element have been joined to each other by mainly using silver paste. However, along with the recent downsizing and performance enhancement of the semiconductor element, also the support member used for the semiconductor wafer has required downsizing and miniaturization. However, the silver paste is becoming unable to deal with such a requirement because of the occurrence of failure caused by protrusion and the inclination of the semiconductor element during wire bonding, the difficulty of thickness-control of a bonding portion, and the occurrence of voids at the bonding portion. Therefore, to deal with such a requirement, an adhesive film has been used in place of the silver paste in recent years.

However, since the adhesive film is stuck to a wafer before dicing, if the dicing is performed by cutting using a blade in such a state, the adhesive film as well as the wafer may be diced. In such a case, because of the softness of the adhesive film, there arises a problem in that each chip causes chippings and burrs. Although an adhesive film is stuck to a wafer after dicing and it is diced again by a blade, each chip causes burrs also because of the softness of the adhesive film.

In a dividing processing method in which after modified areas are formed in the inside of a wafer, a dicing tape is expanded to divide the wafer into chips, a proposal is given in which in an expansion step for expanding the dicing tape, an adhesive film is cut using an impulsive force at the time of cutting the wafer by an external force (see e.g. Japanese Patent Laid-open No. 2002-192370).

### SUMMARY OF THE INVENTION

However, if an adhesive film having a fixed thickness or more is used, the adhesive film cannot appropriately be cut by the impulsive force alone at the time of cutting a wafer in an expansion step in some cases. Since the adhesive film is not formed with a predetermined dividing line serving as a division-scale, it is difficult to individually form modified areas in the adhesive film.

Accordingly, it is an object of the present invention to provide a workpiece dividing method of appropriately dividing an adhesive film along predetermined dividing lines of a wafer although the adhesive film is formed thicker than a predetermined thickness.

In accordance with an aspect of the present invention, there is provided a workpiece dividing method of dividing along predetermined dividing lines a workpiece in a state where an adhesive film is stuck to a rear surface of a wafer formed with functional elements in areas sectioned by the predetermined dividing lines on a front surface of the wafer, including: an expansion tape sticking step for providing a state where an adhesive film side of the workpiece is stuck to an expansion tape stuck in an opening portion of an annular frame; a predetermined dividing line detecting step for detecting respective positions of the predetermined dividing lines on the front surface of the wafer; a first modified area forming step in which on the basis of information detected in the predetermined dividing line detecting step, a laser beam with a wavelength that can pass through the wafer from the front surface side of the wafer is focused on and directed to the front surface or inside of the adhesive film to form a first modified area on the front surface of or in the inside of the adhesive film; a second modified area forming step in which on the basis of the information detected in the predetermined dividing line detecting step, a laser beam with a wavelength that can pass through the wafer from the front surface of the wafer is focused on and directed to the inside of the wafer to form a second modified area in the inside of the wafer; and a dividing step for expanding the expansion tape to divide the workpiece along the predetermined dividing lines with the first and second modified areas taken as starting points.

In the present invention, the modified areas are formed in each of the wafer and the adhesive film. Therefore, if the adhesive film is expanded to perform the division along the predetermined dividing lines with both the modified areas taken as starting points, the wafer and the adhesive film can be divided simultaneously and easily. This applies in the case where the adhesive film is formed thick. Because of no use of a blade, it is possible to avoid the occurrence of chippings and/or burrs. Further, although the adhesive film is not formed with the predetermined dividing lines, the predetermined dividing lines formed on the wafer are detected in the predetermined dividing line detecting step and such detection results are made use of to irradiate the adhesive film with a laser beam. Therefore, the control of the laser beam irradiation position can be done easily. Thus, it is possible to easily form a modified area at a portion of the adhesive film below the predetermined dividing line.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view illustrating a state where a workpiece is supported by an annular frame via an expansion tape;

FIG. 2 schematically illustrates the state where the workpiece is supported by the annular frame via the expansion tape;

FIG. 3 is a schematic cross-sectional view illustrating a state of a predetermined dividing line detecting step;

FIG. 4 is a schematic cross-sectional view illustrating a first modified area forming step;

FIG. 5 is a schematic cross-sectional view illustrating a second modified area forming step; and

FIG. 6 is a schematic cross-sectional view of a dividing step.

### DETAILED DESCRIPTION OF THE PREFERRED EMBODIMENTS

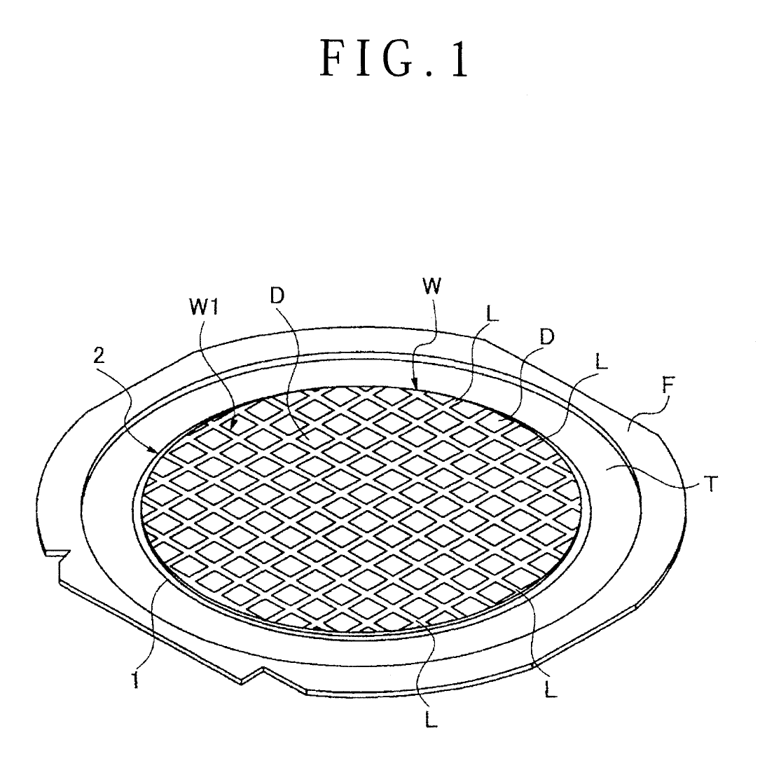

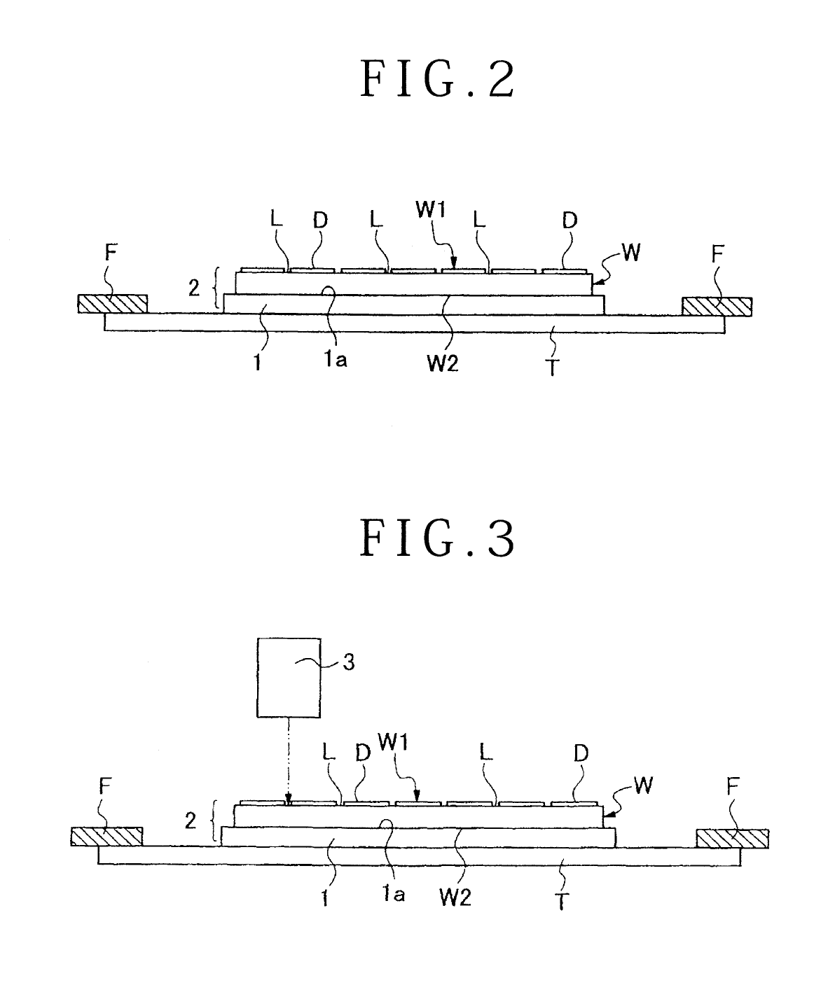

A wafer W illustrated in FIGS. 1 and 2 is configured such that functional elements D are formed on a front surface W1 in respective areas sectioned by predetermined dividing lines L. An adhesive film 1 is stuck to a rear surface W2, an element non-formation surface, of the wafer W. The wafer W and the adhesive film 1 constitute a workpiece 2. The adhesive film 1 is such that a surface on the side where the adhesive film 1 is stuck to the rear surface W2 of the wafer W is a front surface 1a. The wafer W is composed of a semiconductor wafer such as e.g. a silicon wafer or the like. The adhesive film 1 called e.g. a DAF (Die Attach Film) is used.

The workpiece 2 is such that the adhesive film 1 side is stuck to an adhesive surface of the expansion tape T. An annular frame F is stuck to an outer circumferential portion of the expansion tape T in such a manner that the expansion tape T stuck to the annular frame F closes an opening portion of the annular frame. The adhesive film 1 side of the workpiece 2 is stuck to a portion of the expansion tape T closing the opening portion. In this way, the workpiece 2 is integrally supported by the annular frame F via the expansion tape T (an expansion tape sticking step).

As described above, in the state where the workpiece 2 is integrally supported by the annular frame F via the expansion tape T, image pickup means 3 such as a CCD camera or the like is used to pick up an image from the front surface W1 side of the wafer W as illustrated in FIG. 3. In addition, the predetermined dividing lines L of the front surface W1 are detected through pattern matching or other processing and their positions are stored by a control means not illustrated (the predetermined dividing line detecting step).

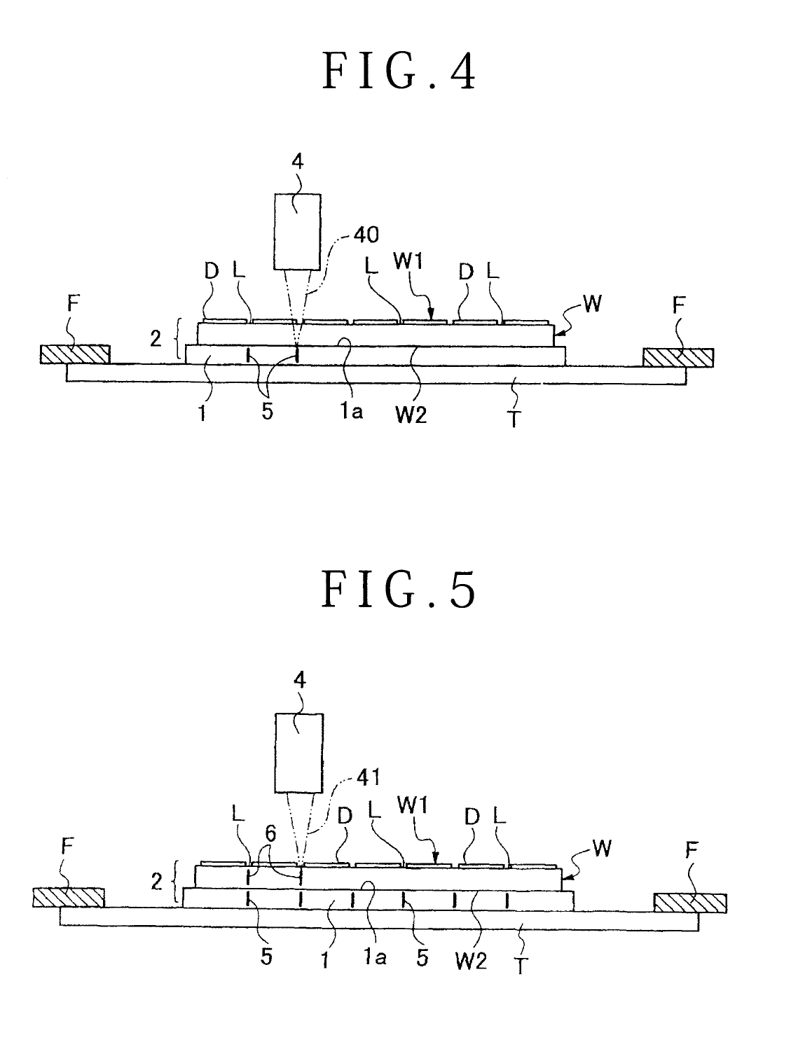

On the basis of the positional information of the predetermined dividing lines L detected by in the predetermined dividing line detecting step, the control means brings a laser beam irradiation section 4 at a position above the predetermined dividing line L as illustrated in FIG. 4. While the workpiece 2 integral with the annular frame F via the expansion tape T and the laser beam irradiation section 4 are horizontally processing-transferred in a relative manner, a laser beam 40 with a wavelength that can pass through the wafer W and the adhesive film 1 is directed to the predetermined dividing line L. At this time, the laser beam 40 is focused on the front surface 1a or inside of the adhesive film 1 to form a modified area 5 on the front surface 1a of or in the inside of the adhesive film 1. In this case, for example, the conditions of the laser beam 40 are set as below.
Average output: 1.4 [W]
Frequency: 90 [kHz]
Wavelength: 1000-1600 [nm]
Processing-transfer rate: 340 [mm/s]
Focal point: set at a position below the rear surface W2 of the workpiece 2 (depending on the thickness of the adhesive film 1 a plurality of focal points may be set and processing-transfer is carried out a plurality of times in some cases.)

The modified areas 5 illustrated as an example in FIG. 4 are formed inside the adhesive film 1. In this way, the modified areas 5 are each formed on the front surface 1a of or in the inside of a portion, located below a corresponding one of all the predetermined dividing lines L, of the adhesive film 1. The adhesive film 1 is not formed with the predetermined dividing lines. However, the laser beam 40 can be focused on below the predetermined dividing lines L of the wafer W by use of the detection results of the predetermined dividing line detecting step (the first modified area forming step). Thus, the predetermined dividing line detecting step is carried out before the first modified area forming step.

Next, on the basis of the positional information of the predetermined dividing lines L detected in the predetermined dividing line detecting step, the control means bring the laser beam irradiation section 4 at a position above the predetermined dividing line L as illustrated in FIG. 5. While the workpiece 2 integral with the annular frame F via the expansion tape T and the laser beam irradiation section 4 are horizontally processing-transferred in a relative manner, a laser beam 41 with a wavelength that can pass through the wafer W is directed to the predetermined dividing line L. At this time, the laser beam 41 is focused on the inside of the wafer W to form a modified area 6 in the inside of the wafer W. In this case, if the workpiece 2 is silicon and has a thickness of 500 μm, the conditions of the laser beam 41 are set as below.
Average output: 1.4 [W]
Frequency: 90 [kHz]
Wavelength: 1000-1600 [nm]
Processing-transfer rate: 340 [mm/s]
Focal point: eight-layered focal points are set in the workpiece 2 and processing-transfers are carried out eight times. The formation of the modified areas 6 is carried out so as to correspond to all the predetermined dividing lines L (the second modified area forming step).

Incidentally, the modified area formed in each of the first and second modified area forming steps is an area in the state where any of density, a refractive index, mechanical strength and other physical characteristics is different from that in the circumference thereof. For example, the modified area is a fusing processing area, a cracking area, an insulation breakdown area, a refractive index varying area or the like, or an area where these are mixed.

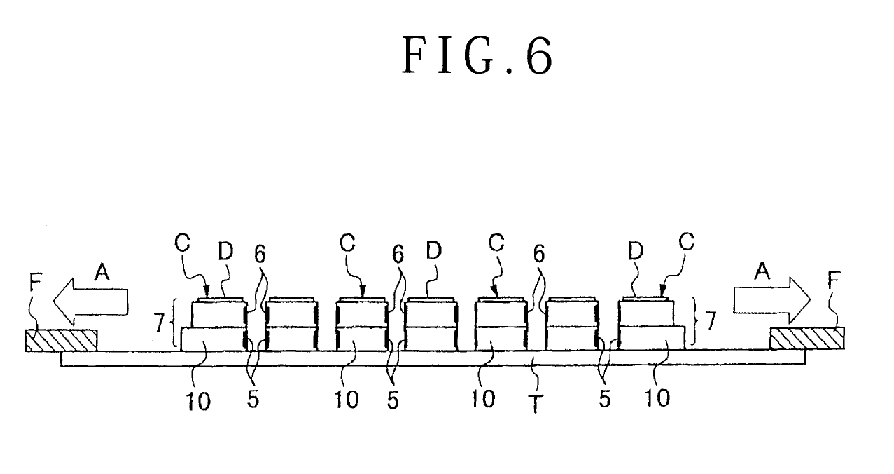

After the respective modified areas 5 and 6 are formed on the front surface 1a of or in the inside of the adhesive film 1 and in the inside of the wafer W, respectively, the expansion tape T is stretched and expanded in a horizontal direction (in an arrow-A direction in FIG. 6) as illustrated in FIG. 6. In this way, the wafer W and the adhesive film 1, i.e., the workpiece 2 are divided along all the predetermined dividing lines L from the modified areas 5 of the adhesive film 1 and the modified areas 6 of the wafer W as starting points. Consequently, individual devices 7 composed of chips C and the adhesive films 10 stuck to the corresponding rear surfaces of the chips are formed (the dividing step).

As described above, the modified areas are formed in each of the wafer W and the adhesive film 1. Therefore, in the dividing step, the wafer W and the adhesive film 1 can be divided simultaneously and easily by expanding the expansion tape T. Although the adhesive film 1 is formed thick, it can be divided simultaneously and easily. Since a blade is not used, it is possible to avoid the occurrence of chippings and/or burrs on the chip C.

Incidentally, in the embodiment described above, the expansion tape sticking step is carried out first; however, it may be carried out any time if before the dividing step. Therefore, the expansion tape sticking step may be carried out after the first and second modified area forming steps.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A workpiece dividing method of dividing along predetermined dividing lines a workpiece in a state where an adhesive film is stuck to a rear surface of a wafer formed with functional elements in areas sectioned by the predetermined dividing lines on a front surface of the wafer, comprising:
an expansion tape sticking step for providing a state where an adhesive film side of the workpiece is stuck to an expansion tape stuck in an opening portion of an annular frame;
a predetermined dividing line detecting step for detecting respective positions of the predetermined dividing lines on the front surface of the wafer;
a first modified area forming step in which on the basis of information detected in the predetermined dividing line detecting step, a laser beam with a wavelength that can pass through the wafer from the front surface side of the wafer is focused on and directed to the front surface or inside of the adhesive film to form a first modified area on the front surface of or in the inside of the adhesive film;
a second modified area forming step in which on the basis of the information detected in the predetermined dividing line detecting step, a laser beam with a wavelength that can pass through the wafer from the front surface of the wafer is focused on and directed to the inside of the wafer to form a second modified area in the inside of the wafer; and
a dividing step for expanding the expansion tape to divide the workpiece along the predetermined dividing lines with the first and second modified areas taken as starting points.
